(19) United States
(12) Patent Application Publication
(10) Pub. No.: US 2024/0047505 A1
(43) Pub. Date: Feb. 8, 2024

(54) OPTOELECTRONIC DEVICE WITH AXIAL THREE-DIMENSIONAL LIGHT-EMITTING DIODES

(71) Applicant: Aledia, Echirolles (FR)

(72) Inventors: Mehdi Daanoune, Renage (FR); Jérôme Napierala, Saint Egrève (FR); Vishnuvarthan Kumaresan, Lyon (FR); Philippe Gilet, Teche (FR); Marjorie Marra, Tullins (FR)

(73) Assignee: Aledia, Echirolles (FR)

(21) Appl. No.: 18/267,071

(22) PCT Filed: Dec. 15, 2021
(86) PCT No.: PCT/EP2021/086030

§ 371 Date: Jun. 13, 2023

(30) Foreign Application Priority Data
Dec. 17, 2020 (FR) FR2013521

(51) Int. Cl. H01L 27/15; H01L 33/18; H01L 33/44; H01L 33/10; H01L 33/00

(52) U.S. Cl. CPC H01L 27/156; H01L 33/18; H01L 33/44; H01L 33/10; H01L 33/0093; H01L 2933/0083

(57) ABSTRACT

An optoelectronic device including an array of axial light-emitting diodes (LED), each including an active area configured to emit electromagnetic radiation whose emission spectrum includes a maximum at a first wavelength. The device further includes a cladding for each LED, transparent to said radiation of a first material surrounding the sidewalls of the LED over at least a portion of the LED, each cladding having a thickness greater than 10 nm. The device further comprises layer, between the claddings, transparent to said radiation, made of a second material different from the first material, the second material being electrically insulating, the array forming a photonic crystal.

The present patent application claims the priority of the French patent application FR20/13521, which will be considered as part of the present description.

### TECHNICAL FIELD

The present disclosure relates to an optoelectronic device, in particular a display screen or an image projection device comprising light-emitting diodes [LEDs] based on semiconductor materials, and their manufacturing methods.

### BACKGROUND ART

A LED based on semiconductor materials generally includes an active area that is the LED region from which the majority of the electromagnetic radiation provided by the LED is emitted. The structure and composition of the active area is adapted to provide electromagnetic radiation with the desired properties.

Of particular interest here are optoelectronic devices with axial-type three-dimensional LEDs, i.e. electroluminescent diodes that each comprise a three-dimensional semiconductor element, extending along a preferred direction and comprising the active area at an axial end of the three-dimensional semiconductor element.

Examples of three-dimensional semiconductor elements are microwires or nanowires comprising a semiconductor material having a majority of at least one Group III element and one Group V element (such as gallium nitride (GaN)), hereinafter referred to as III-V compound, or having a majority of at least one Group II element and one Group VI element (such as zinc oxide (ZnO)), hereinafter referred to as II-VI compound, or having a majority of at least one Group IV element. Such devices are described in French patent applications FR 2995729 and FR 2997558, for example.

Making an active area containing confinement means, in particular a single or multiple quantum wells, is known. A single quantum well is made by interposing a layer of a second semiconductor material between two layers of a first semiconductor material such as a Group III-V compound, in particular GaN, respectively doped with an P and N type such as an alloy of the Group III-V compound and a third element, in particular InGaN, whose band gap is different from the first semiconductor material. A multiple quantum well structure comprises a stack of semiconductor layers forming alternating quantum wells and barrier layers.

The electromagnetic radiation wavelength emitted by the active area of the optoelectronic device depends in particular on the dimensions of the active area, and in particular on the average diameter of the active area. Moreover, the quantum efficiency of the active area depends in particular on the crystalline quality of the layers composing the active area. The crystalline quality of the layers making up the active area tends to deteriorate as the average active area diameter increases.

The LEDs can be arranged in an LED array so as to form a photonic crystal. In particular, the photonic crystal makes it possible to obtain a light beam emitted by the LED array along a preferred direction. The photonic crystal also makes it possible to filter the wavelength of the radiation emitted by the LED array, to favor the emission of a narrow spectrum radiation, for example. In particular, the properties of the photonic crystal depend on the pitch of the LEDs in the LED array and the average diameter of the LEDs.

One drawback is that the average diameter of the LEDs enabling the preferred radiation emission from each LED at the desired wavelength while still allowing for a suitable crystal quality may be different from the average LED diameter that allows for obtaining a photonic crystal with the desired properties.

### SUMMARY OF INVENTION

Thus, an object of one embodiment is to address all or some of the drawbacks of the LED optoelectronic devices described above.

Another object of one embodiment is that the active area of each LED comprises a stack of layers of semiconductor materials based on a Group III-V compound, or a Group II-VI compound, or a Group IV semiconductor or compound.

It is a further object of one embodiment that the emission spectrum of the active areas of the axial type of three-dimensional LEDs based on a Group III-V compound, or a Group II-VI compound, or a Group IV semiconductor or compound has the desired properties.

It is a further object of one embodiment that the optoelectronic device comprises a LED array forming a photonic crystal having the desired properties.

Another object of one embodiment is that the active areas of the LEDs have good crystal quality.

One embodiment provides an optoelectronic device comprising an array of axial LEDs, each comprising an active area configured to emit electromagnetic radiation, whose emission spectrum comprises a maximum at a first wavelength. The device further comprises a cladding for each LED, transparent to said radiation of a first material surrounding the sidewalls of the LED over at least a portion of the LED, each cladding having a thickness greater than 10 nm. The device further comprises a layer between the claddings, transparent to said radiation of a second material, different from the first material, the second material being electrically insulating, the array forming a photonic crystal. The properties of the photonic crystal are advantageously chosen so that the array of coated LEDs forms a resonant cavity, in particular to achieve a coupling and increase the selection effect. This allows the intensity of the radiation emitted by the set of cladded LEDs of the array by the emission surface of the optoelectronic device to be amplified for certain wavelengths compared to a set of cladded LEDs that would not form a photonic crystal.

This makes it possible to dissociate the photonic crystal properties which depend essentially on the LED pitch and the average external diameter of the cladding LED assembly, as a first approximation, from the emission properties of the active area of the LED, which depend essentially on the average diameter of the LED in the absence of cladding, as a first approximation.

According to one embodiment, each cladding has a thickness greater than 20 nm. This allows the claddings to alter the optical properties of the photonic crystal as compared to a LED array without claddings.

According to one embodiment, the refractive index of the first material at the first wavelength is strictly greater than the refractive index of the second material at the first wavelength. This allows the claddings to alter the optical properties of the photonic crystal as compared to a LED array without claddings.

According to one embodiment, the difference between the refractive index of the first material at the first wavelength and the refractive index of the second material at the first wavelength is greater than 0.5. The greater the difference between the refractive index of the first material at the first wavelength and the refractive index of the second material at the first wavelength, the more efficient the photonic crystal is and the easier it is to change the properties of the photonic crystal by varying the thickness of the claddings.

According to one embodiment, each LED comprises a semiconductor element made of a third material and at least partially surrounded by said cladding, the difference between the refractive index of the first material and the refractive index of the third material is less than 0.5, and preferably less than 0.3. This provides refractive index homogeneity between the first and third materials that allows for the formation of an efficient photonic crystal and allows for simplification of the optoelectronic device design.

According to one embodiment, the first material is electrically insulating. The protection of the various parts of the LED from short circuits is then achieved by the cladding.

According to one embodiment, the optoelectronic device further comprises an electrically insulating coating for each LED, interposed between the cladding and the LED, the thickness of the coating being less than 10 nm. The protection of the individual parts of the LED against short circuits is then achieved by the electrically insulating coating, so that the cladding may not be of an insulating material. This advantageously offers more freedom in the choice of the material making up the cladding.

According to one embodiment, the LEDs each comprise a portion of a Group III-V compound, a Group II-VI compound, or a Group IV semiconductor or compound. This makes it possible to make LEDs according to known methods.

According to one embodiment, the first material is silicon nitride or titanium oxide. This makes it possible to use a first material whose refractive index at the first wavelength is close to the refractive index at the first wavelength of the materials making up the LEDs.

According to one embodiment, the second material is silicon oxide. This makes it possible to obtain a high difference between the refractive index at the first wavelength of the first material and the refractive index at the second wavelength of the second material.

According to one embodiment, the photonic crystal is configured to form a resonance peak amplifying the intensity of said electromagnetic radiation, at at least a second wavelength different from or equal to the first wavelength. Advantageously, when the resonance peak is at the first wavelength, this increases the intensity of the radiation emitted at the first wavelength and makes the emission spectrum narrower and centered at the first wavelength. Dissociating the dimensions of the array and the dimensions of each LED makes it easier to design the photonic crystal forming a resonant peak at the first wavelength.

According to one embodiment, the optoelectronic device comprises a support on which the LEDs rest, each LED comprising a stack of a first semiconductor portion resting on the support, the active area in contact with the first semiconductor portion and a second semiconductor portion in contact with the active area.

According to one embodiment, the device comprises a reflective layer between the support and the first semiconductor portions of the LEDs. This improves the extraction of light from the optoelectronic device.

According to one embodiment, the reflective layer is metal.

According to one embodiment, the second semiconductor portions of the LEDs are covered with a conductive layer and at least partially transparent to the radiation emitted by the LEDs.

One embodiment also provides a method for designing an optoelectronic device comprising axial LEDs, each comprising an active area, the method comprising the following steps:
determining the LED dimensions such that each active area emits electromagnetic radiation whose emission spectrum includes a maximum at a first wavelength; and
determining an array of said LEDs comprising a cladding for each LED, transparent to said radiation of a first material surrounding the sidewalls of the LED over at least a portion of the LED, each cladding having a thickness greater than 10 nm, further comprising a layer between the claddings of a second material, different from the first material, the second material being electrically insulating, to obtain a photonic crystal.

One embodiment also provides for a method of manufacturing an optoelectronic device comprising an array of axial LEDs each comprising an active area configured to emit electromagnetic radiation whose emission spectrum comprises a maximum at a first wavelength, the device further comprising a cladding for each LED, transparent to said radiation made of a first material surrounding the sidewalls of the LED over at least a portion of the LED, each cladding having a thickness greater than 10 nm, the device further comprising a layer between the claddings, made of a second material, different from the first material, the second material being electrically insulating, the array forming a photonic crystal.

According to one embodiment, forming the LEDs comprises the following steps:
forming second semiconductor portions on a substrate, the second semiconductor portions being separated from each other by the pitch of the array;
forming an active area on each second semiconductor portion;
forming a first semiconductor portion on each active area;
forming the cladding for each LED, of a first material surrounding the sidewalls of at least part of the first portion, and/or of the second portion, and/or of the active area; and
forming the layer of the second material.

According to one embodiment, the method comprises a step of removing the substrate. This makes it possible to use a substrate suitable for forming the LEDs.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1 is a schematic, partial, cross-sectional view of one embodiment of an optoelectronic device comprising LEDs;

FIG. 2 is a schematic, partial perspective view of the optoelectronic device shown in FIG. 1;

FIG. 3 shows schematically an example of the arrangement of the LEDs of the optoelectronic device shown in FIG. 1;

FIG. 4 shows schematically another example of the arrangement of LEDs of the optoelectronic device shown in FIG. 1;

FIG. 5 is a schematic, partial, cross-sectional view of another embodiment of an optoelectronic device comprising LEDs;

FIG. 6 is a grayscale map of the light intensity emitted by uncladded LEDs of a photonic crystal depending on the wavelength and direction of the emitted radiation;

FIG. 7 is a grayscale map of the light intensity emitted by cladded LEDs of a photonic crystal depending on the wavelength and direction of the emitted radiation;

FIG. 8 shows evolution curves of the light intensity of the radiation emitted by an array of LEDs depending on the wavelength measured along a first direction for uncladded LEDs and coated LEDs; and

FIG. 9 shows a curve of the light intensity of the radiation emitted by an array of LEDs depending on the wavelength measured along a second direction for cladded LEDs;

FIG. 10A shows a step of one embodiment of a method for manufacturing the optoelectronic device shown in FIG. 1;

FIG. 10B illustrates another step of the manufacturing method;

FIG. 10C illustrates another step of the manufacturing method;

FIG. 10D illustrates another step in the manufacturing method;

FIG. 10E illustrates another step in the manufacturing method;

FIG. 10F illustrates another step in the manufacturing method; and

FIG. 10G illustrates another step of the manufacturing method.

### DESCRIPTION OF EMBODIMENTS

Like features have been designated by like references in the various figures. In particular, the structural and/or functional features that are common among the various embodiments may have the same references and may dispose identical structural, dimensional and material properties. For the sake of clarity, only the operations and elements that are useful for an understanding of the embodiments described herein have been illustrated and described in detail. In particular, the optoelectronic devices considered may include other components that will not be detailed.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures or to an optoelectronic device in a normal position of use.

Unless specified otherwise, the expressions “around”, “approximately”, “substantially” and “in the order of” signify within 10%, and preferably within 5%. In addition, the terms “insulator” and “conductor” are herein understood to mean “electrically insulating” and “electrically conductive,” respectively.

In the following description, the internal transmittance of a layer is the ratio of the radiation intensity exiting the layer to the radiation intensity entering the layer. The layer absorption is equal to the difference between 1 and the internal transmittance. In the remainder of the description, a layer is said to be transparent to radiation when the radiation absorption through the layer is less than 60%. In the remainder of the description, a layer is said to be radiation absorbent when the radiation absorption in the layer is greater than 60%. When radiation has a generally “bell-shaped” spectrum, such as a Gaussian spectrum, having a maximum, the radiation wavelength or central or main radiation wavelength, is called the wavelength at which the maximum of the spectrum is reached. In the remainder of the description, the refractive index of a material refers to the refractive index of the material for the wavelength range of the radiation emitted by the optoelectronic device. Unless otherwise specified, the refractive index is considered to be substantially constant over the wavelength range of the useful radiation, equal to the average of the refractive index over the wavelength range of the radiation emitted by the optoelectronic device, for example.

An axial LED means a three-dimensional structure of an elongated shape, such as cylindrical, along a preferred direction, with at least two dimensions, called minor dimensions, of between 5 nm and 2.5 μm, preferably between 50 nm and 2.5 μm. The third dimension, referred to as the major dimension, is greater than or equal to 1 time, preferably greater than or equal to 5 times and even more preferably greater than or equal to 10 times, the largest of the minor dimensions. In some embodiments, the minor dimensions may be less than or equal to about 1 μm, preferably between 100 nm and 1 μm, more preferably between 100 nm and 800 nm. In some embodiments, the height of each LED may be greater than or equal to 500 nm, preferably between 1 μm and 50 μm.

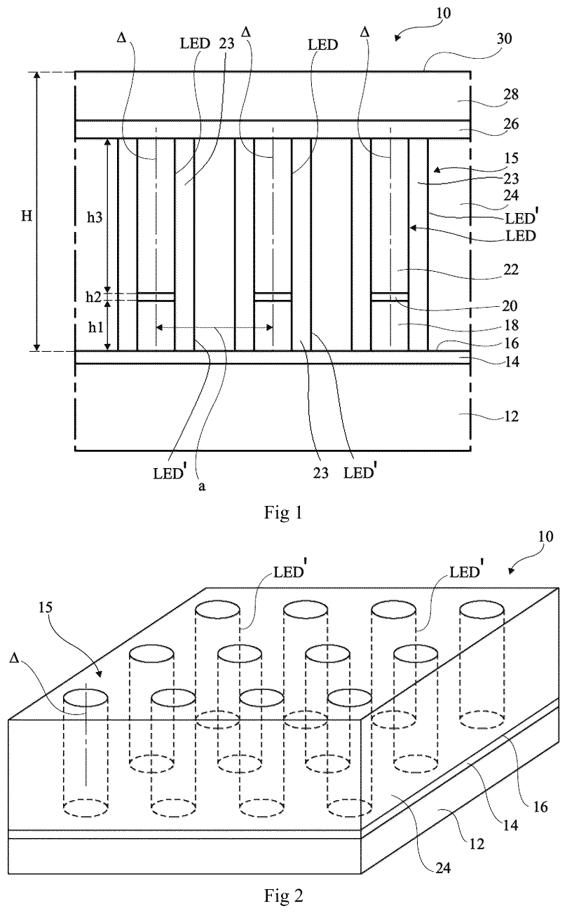

FIGS. 1 and 2 are respectively a schematic partial side section view and perspective view of one embodiment of an optoelectronic device 10 with LEDs.

From bottom to top in FIG. 1, the optoelectronic device 10 comprises:
a support 12;
a first electrode layer 14 resting on the support 12 and having a top surface 16;
an array 15 of axial light-emitting diodes LED resting on the surface 16, each axial LED comprising, from bottom to top in FIG. 1, a lower semiconductor portion 18, not shown in FIG. 2, in contact with the electrode layer 14, an active area 20, not shown in FIG. 2, in contact with the semiconductor portion 18, and an upper semiconductor portion 22, not shown in FIG. 2, in contact with the active area 20;
for each axial light-emitting diode LED, an insulating cladding 23, not shown in FIG. 2, of a first insulating material surrounding the side wall of the light-emitting diode LED over at least part of the height of the light-emitting diode LED the assembly comprising the light-emitting diode LED and the insulating cladding 23 surrounding the light-emitting diode LED forming a cladded electroluminescent diode LED′, with only the contours of the cladded electroluminescent diodes LED′ shown in FIG. 2;
an insulating layer 24 of a second insulating material extending between the cladded electroluminescent diodes LED′ over the entire height of the cladded electroluminescent diodes LED;
a second electrode layer 26, not shown in FIG. 2, overlying the light-emitting diodes LED in contact with the top portions 22 of the light-emitting diodes LED; and
a coating 28, not shown in FIG. 2, overlying the second electrode layer 26, and defining an emission surface 30 of the optoelectronic device 10.

Each light-emitting diode LED is said to be axial, in that the active area 20 is in the extension of the lower portion 18 and the upper portion 22 is in the extension of the active area 20, the assembly comprising the lower portion 18, the active area 20 and the upper portion 22 extending along an axis A called the axial LED axis. Preferably, the axes of the light-emitting diode LED are parallel and orthogonal to the surface 16.

The support 12 may correspond to an electronic circuit. The electrode layer 14 may be a metal such as silver, copper or zinc. As an example, the electrode layer 14 has a thickness of between 0.01 μm and 10 μm. The electrode layer 14 may completely cover the support 12. In a variant, the electrode layer 14 may be divided into separate portions so as to enable separate control of LED groups of the LED array. According to one embodiment, the surface 16 may be reflective. The electrode layer 14 may then exhibit specular reflection. According to another embodiment, the electrode layer 14 may exhibit Lambertian reflection. One way to achieve a surface exhibiting Lambertian reflection is to create irregularities on a conductive surface. As an example, when the surface 16 corresponds to the surface of a conductive layer resting on a base, a texturing of the surface of the base can be performed prior to deposition of the metal layer so that the surface 16 of the metal layer, once deposited, has reliefs.

The second electrode layer 26 is conductive and transparent. According to one embodiment, the electrode layer 26 is a transparent and conductive oxide (TCO) layer, such as indium tin oxide (or ITO), zinc oxide, doped or undoped with aluminum or gallium, or graphene. As an example, the electrode layer 26 has a thickness of between 5 nm and 200 nm, preferably between 20 nm and 50 nm. The coating 28 may include an optical filter, or optical filters arranged next to each other.

In the embodiment shown in FIGS. 1 and 2, all the light-emitting diodes LED have the same height. For example, the thickness of the insulating layer 24 is chosen to be equal to the height of the light-emitting diodes LED such that the top surface of the insulating layer 24 is coplanar with the top surfaces of the LEDs.

According to one embodiment, the semiconductor portions 18 and 22 and the active areas 20 are made of a semiconductor material, at least in part. The semiconductor material is selected from the group consisting of III-V compounds, II-VI compounds, and Group IV semiconductors or compounds. Examples of Group III elements include gallium (Ga), indium (In) or aluminum (Al). Examples of Group IV elements include nitrogen (N), phosphorus (P) or arsenic (As). Examples of III-N compounds are GaN, AN, InN, InGaN, AlGaN or AlInGaN. Examples of Group II elements include Group IIA elements, including beryllium (Be) and magnesium (Mg) and Group IIB elements including zinc (Zn), cadmium (Cd), and mercury (Hg). Examples of Group VI elements include Group VIA elements, including oxygen (O) and tellurium (Te). Examples of Group II-VI compounds are ZnO, ZnMgO, CdZnO, CdZnMgO, CdHgTe, CdTe or HgTe. In general, the elements in compound III-V or II-VI can be combined with different molar fractions. Examples of Group IV semiconductor materials are silicon (Si), carbon (C), germanium (Ge), silicon carbide (SiC) alloys, silicon-germanium (SiGe) alloys or germanium carbide (GeC) alloys. The semiconductor portions 18 and 22 may include a dopant. As an example, for III-V compounds, the dopant may be selected from the group consisting of a Group II P-type dopant such as magnesium (Mg), zinc (Zn), cadmium (Cd) or mercury (Hg), a Group IV P-type dopant such as carbon (C) or a Group IV N-type dopant such as silicon (Si), germanium (Ge), selenium (Se), sulfur (S), terbium (Tb) or tin (Sn). Preferably, the semiconductor portion 18 is P-doped GaN and the semiconductor portion 22 is N-doped GaN.

For each light-emitting diode LED, the active area 20 may include containment means. As an example, the active area 20 may include a single quantum well. It then comprises a semiconductor material different from the semiconductor material forming the semiconductor portions 18 and 22, having a band gap less than that of the material forming the semiconductor portions 18 and 22. The active area 20 may comprise multiple quantum wells. In this case, it comprises a stack of semiconductor layers forming alternating quantum wells and barrier layers.

In FIGS. 1 and 2, each light-emitting diode LED has the shape of a cylinder with a circular base with a Δ axis. However, each light-emitting diode LED may have the shape of a cylinder with a Δ axis and a polygonal base, such as square, rectangular, or hexagonal. Preferably, each light-emitting diode LED has the shape of a cylinder with a hexagonal base.

The sum of the height h1 of the bottom portion 18, the height h2 of the active area 20, the height h3 of the top portion 22, the thickness of the electrode layer 26, and the thickness of the coating 28 is referred to as the height H of the light-emitting diode LED.

The first insulating material comprising the insulating jackets 23 is transparent to the radiation wavelengths emitted by the light-emitting diodes LED. The refractive index of the first insulating material is strictly greater than the refractive index of the second insulating material. According to one embodiment, the cladded electroluminescent diodes LED′ are arranged to form a photonic crystal. To have an effective photonic crystal, it is desirable to have the largest refractive index gap between the first insulating material and the second insulating material. Preferably, the difference between the refractive index of the first insulating material and the refractive index of the material making up the lower and upper portions 18, 22 of the LEDs is as small as possible, so that the cladding 23 forms an “extension” of the lower and upper portions 18, 22 of the LEDs, from an optical viewpoint. The difference between the refractive index of the first insulating material and the refractive index of the second insulating material is preferably greater than 0.5, more preferably greater than 0.6, ideally greater than 1. Preferably, the difference between the refractive index of the first insulating material and the refractive index of the material making up the lower and upper portions 18, 22 of the LEDs is less than 0.5, and preferably less than 0.3. The refractive index of the first insulating material is preferably between 2 and 2.5 when the material comprising the bottom and top portions 18, 22 of the LEDs is GaN based. According to one embodiment, the first insulating material composing the insulating jackets 23 is silicon nitride (Sᵢ₃N₄), or titanium oxide (TᵢO₂). According to one embodiment, the insulating cladding 23 extends over the entire lower portion 18, the active area 20 and the upper portion 22 of the corresponding light-emitting diode LED. According to another embodiment, the insulating cladding 23 extends over only a part of the lower portion 18, and/or the active area 20, and/or the upper portion 22 of the corresponding light-emitting diode LED. The thickness of the insulating cladding 23 is greater than 10 nm, preferably between 15 nm and 150 nm, more preferably between 15 nm and 50 nm. In general, the thickness of the insulating cladding 23 can vary significantly, in particular depending on the desired properties of the photonic crystal. According to one embodiment, the thickness of the insulating cladding 23 is substantially constant. However, the insulating cladding 23 may not be present over the entire height of the lower portion 18, and/or the active area 20, and/or the upper portion 22 of the light-emitting diode LED.

According to one embodiment, the second insulating material comprising the insulating layer 24 is transparent to the radiation wavelengths emitted by the light-emitting diodes LED. The refractive index of the second material is less than 1.6, preferably between 1.3 and 1.56. The insulating layer 24 may be made of an inorganic material such as silicon oxide (SiO₂). The insulating layer 24 may be of an organic material, for example, a benzocyclobutene (BCB) or parylene-based insulating polymer.

According to one embodiment, the cladded electroluminescent diodes LED′ are arranged to form a photonic crystal. Twelve cladded electroluminescent diodes LED′ are shown as an example in FIG. 2, but in practice, the array 15 may comprise between 7 and 100,000 electroluminescent cladded electroluminescent diodes LED′.

The cladded electroluminescent diodes LED′ of the array 15 are arranged in rows and columns (3 rows and 4 columns being shown as an example in FIG. 2). The pitch ‘a’ of the array 15 is the distance between the axis of a cladded electroluminescent diode LED′ and the axis of a nearby cladded electroluminescent diode LED′ in the same or adjacent row. The pitch a is substantially constant. More specifically, the pitch a of the array is chosen such that the array 15 forms a photonic crystal. The photonic crystal formed is a photonic crystal 2D, for example.

The properties of the photonic crystal formed by the array 15 are advantageously chosen so that the array 15 of the cladded electroluminescent diodes LED′ forms a resonant cavity in the plane perpendicular to the Δ axis and a resonant cavity along the Δ axis, in particular to obtain a coupling and to increase the selection effect. This allows the intensity of the radiation emitted by the set of cladded electroluminescent diodes LED′ of the array 15 through the emission surface 30 to be amplified for certain wavelengths compared to a set of electroluminescent cladded LEDs that would not form a photonic crystal.

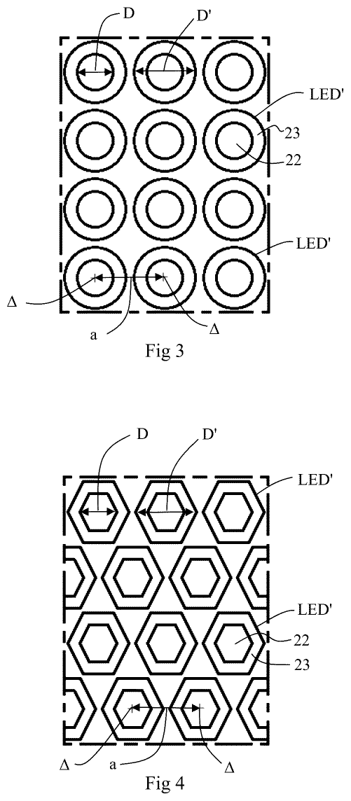

FIGS. 3 and 4 are cross-sectional views, in a plane parallel to the surface 16, schematically illustrating example arrangements of the cladded electroluminescent diodes LED′ of the array 15. In particular, FIG. 3 illustrates a so-called square mesh arrangement and FIG. 4 illustrates a so-called hexagonal mesh arrangement.

FIGS. 3 and 4 each show four rows of LEDs. In the arrangement shown in FIG. 3, each cladded electroluminescent diode LED′ is located at the intersection of a row and a column, with the rows being perpendicular to the columns. Further, in the arrangement illustrated in FIG. 3, the light-emitting diodes LED are circular cross-sectional area of diameter D in a plane parallel to the surface 16 and the cladded electroluminescent diodes LED′ are circular cross-sectional areas of diameter D′ in a plane parallel to the surface 16. In the arrangement shown in FIG. 4, the cladded electroluminescent diodes LED′ on one line are offset by half the pitch a from the cladded electroluminescent diodes LED′ on the previous and next line. Furthermore, in the arrangement illustrated in FIG. 4, the light-emitting diodes LED are hexagonal cross-sectional with average diameter D in a plane parallel to the surface 16 and the cladded LEDs are hexagonal cross-sectional with average diameter D′ in a plane parallel to the surface 16. In the remainder of the description, the average diameter of an element in a plane is referred to as the diameter of the disk having the same area as the area of the cross-section of the element in this plane. In a variant, the cross-section of the cladded electroluminescent diode LED′ may be different from the cross-section of the light-emitting diode LED contained therein. As an example, the cross-section of the cladded electroluminescent diode LED′ may be circular while the cross-section of the light-emitting diode LED therein may be hexagonal.

In the case of a hexagonal array arrangement or a square array arrangement, the diameter D′ may be between 0.05 μm and 2 μm. The pitch a can be between 0.1 μm and 4 μm.

Further, according to one embodiment, the height H of the LED is selected so that each light-emitting diode LED forms a resonant cavity along the Δ axis at the desired center wavelength λ of the radiation emitted by the optoelectronic device 10. According to one embodiment, the height H is chosen to be substantially proportional to k*(λ/2)*neff, where neff is the effective refractive index of the light-emitting diode LED in the optical mode of interest and k is a positive integer. The effective refractive index is defined, for example, in the book “Semiconductor Optoelectronic Devices: Introduction to Physics and Simulation” by Joachim Piprek.

In the case where the LEDs are divided into LED groups emitting at different center wavelengths, the height H can nevertheless be the same for all the LEDs. It can then be determined from the theoretical heights that make it possible to obtain resonant cavities for the LEDs of each group, and is equal to the average of these theoretical heights, for example.

According to one embodiment, the properties of the photonic crystal formed by the array 15 of cladded light-emitting diodes LED′ are selected to increase the light intensity emitted by the array 15 of light-emitting diodes LED at at least one target wavelength. According to one embodiment, the active area 20 of each light-emitting diode LED has an emission spectrum whose maximum is at a center wavelength different from the target wavelength. However, the emission spectrum of the active area 20 overlaps the target wavelength, i.e. the emission spectrum energy of the active area 20 at the target wavelength is not zero. This makes it possible to select an average diameter D for the light-emitting diodes LED makes the manufacture of active areas 20 with suitable crystal quality possible. The fact that the cladding 23, for each light-emitting diode LED, may cover the sidewalls of the light-emitting diode LED only over a portion of the height of the sidewalls makes it possible to use an additional parameter, in addition to the thickness of the insulating cladding 23, to be used to select the desired properties of the photonic crystal.

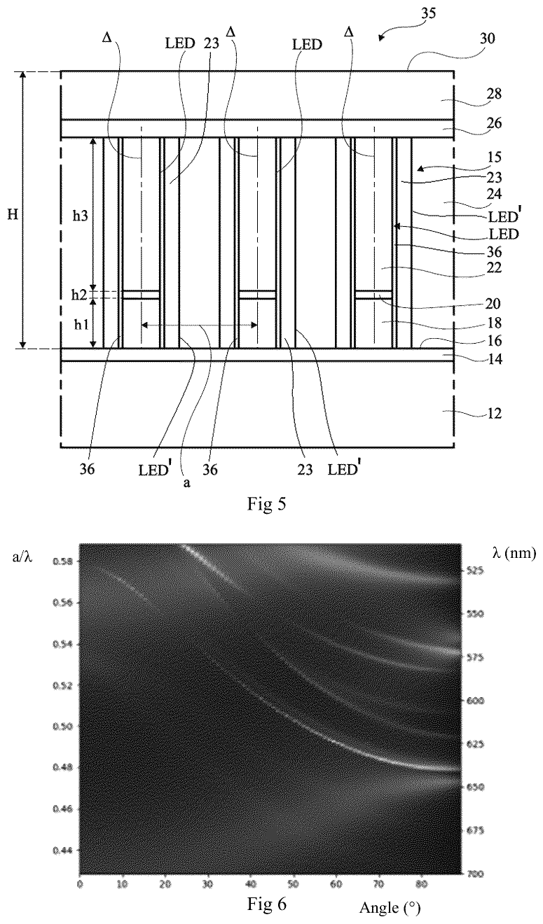

FIG. 5 is a schematic partial cross-sectional view of another embodiment of an optoelectronic device 35 comprising LEDs. The optoelectronic device 35 comprises all the elements of the optoelectronic device 10 shown in FIG. 1, and further includes an insulating coating 36, for each light-emitting diode LED, interposed between the cladding 23 and the light-emitting diode LED. The insulating coating 36 may correspond to a layer having a thickness of less than 10 nm, preferably less than 5 nm. The coating 36 may correspond to a passivation layer. The coating 36 is transparent to the radiation emitted by the LED. The coating 36 is sufficiently thin to make a negligible contribution to the average refractive index of the assembly comprising the cladding 23, the coating 36, and the LED. The prevention of short circuits between the different portions of the light-emitting diode LED is achieved by the coating 36, so that the cladding 23 may not be of an insulating material. This advantageously offers more freedom in the choice of the material making up the cladding 23, which may be of an insulating, conductive, or semiconducting material.

Simulations and tests have been performed. For these simulations and tests, for each light-emitting diode LED, the lower semiconductor portion 18 was made of P-doped GaN. The upper semiconductor portion 22 was made of N-doped GaN. The refractive index of the lower and upper portions 18 and 22 was between 2.4 and 2.5. The active area 20 corresponded to a layer of InGaN. The height h2 of the active area 20 was equal to 40 nm. The electrode layer 14 was made of aluminum. The insulating layer 24 was made of BCB-based polymer. The refractive index of the insulating layer 24 was between 1.45 and 1.56.

For the simulations and testing, the LEDs were circular based. The height h3 was equal to between 300 nm and 350 nm, and the total height H was equal to 400 nm. A specular reflection on surface 16 was considered. The pitch a of the photonic crystal was constant and equal to 300 nm.

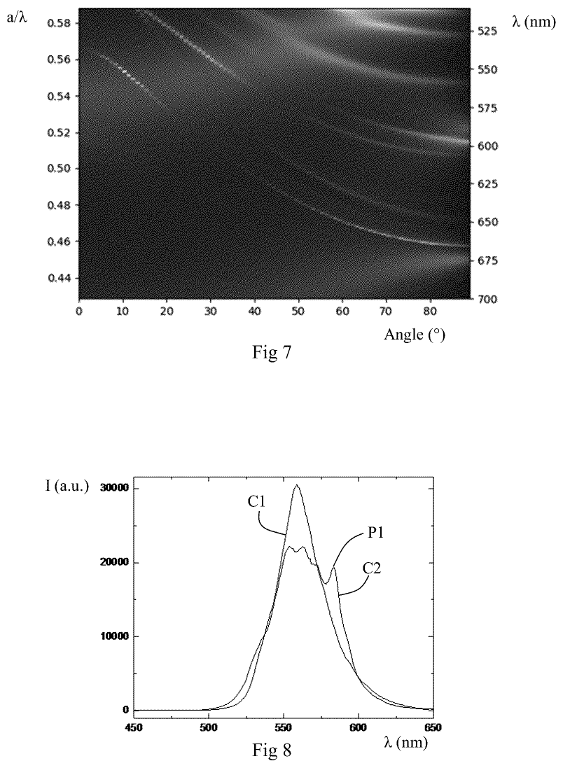

FIGS. 6 and 7 are grayscale maps of the light intensity of the radiation emitted by the LED array 15 depending on the angle between the emission direction and a direction orthogonal to the emitting surface 30, on the x-axis, and depending on the ratio a/λ, where λ is the center wavelength of the radiation emitted by the LEDs, on the y-axis. For FIG. 6, the LEDs were not surrounded by insulating cladding 23. For FIG. 7, each LED was surrounded by insulating cladding 23 made of TiO₂ with a refractive index of between 2.4 and 2.5 and had a thickness of 25 nm. The corresponding values of the central wavelength λ were further indicated in FIGS. 6 and 7 on the right side of the figure. Each of the gray level maps includes brighter areas that correspond to resonance peaks.

The inventors have highlighted that FIG. 7 corresponds substantially to FIG. 6, shifted along the y-axes. This means that a resonance peak present in FIG. 6 is also present in FIG. 7 but is obtained for a lower value of the a/λ ratio. This shows that the photonic crystal properties that depend mainly on the pitch a and the average diameter D′ of the cladded electroluminescent diode LED′ have been substantially decorrelated from the wavelength λ, which depends on the average diameter D of the light-emitting diode LED.

As an example, in FIG. 6, a resonance peak is obtained for an emission angle of and a ratio a/λ equal to about 0.57, which corresponds to a wavelength λ of 530 nm and an average diameter D equal to 240 nm. This same resonance peak is obtained in FIG. 7 for a ratio a/λ equal to about 0.55, which corresponds to an average diameter D′ equal to 260 nm. Thus, it appears that a thickness of the TiO₂ insulating cladding 23 of 25 nm is equivalent to an increase in the average diameter of the LED of about 20 nm.

With further simulations, the inventors have shown that a thickness of the TiO₂ insulating cladding 23 of 30 nm is equivalent to an increase in the average diameter of the LED of about 40 nm, and that a thickness of the TiO₂ insulating cladding 23 of 50 nm is equivalent to an increase in the average diameter of the LED of about 60 nm.

It should be noted that an optimization can be achieved by varying the heights h1 and h3.

Simulations and tests have been carried out with the following parameters: height h1 equal to 100 nm, height h3 equal to 300 nm, height h2 equal to 100 nm, pitch ‘a’ of the photonic crystal equal to 300 nm, and average diameter D equal to 240 nm.

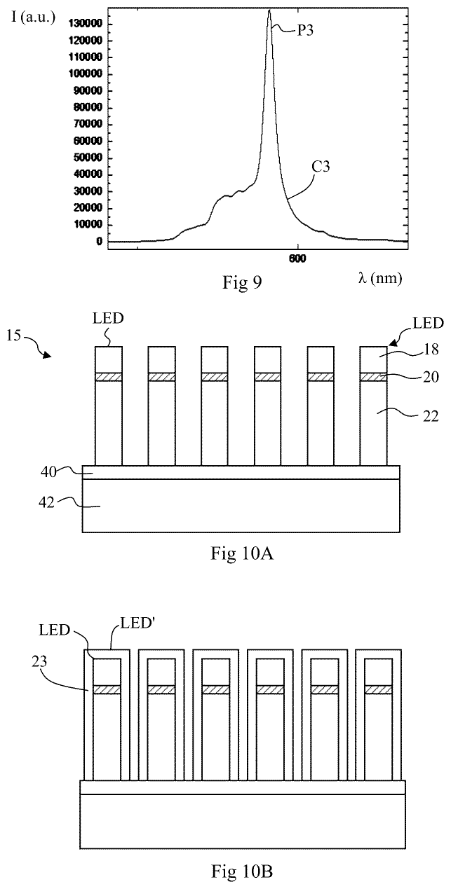

FIG. 8 shows a curve of the evolution C1 of the luminous intensity I, in a direction inclined by +/−24° in relation to a direction perpendicular to the emission surface depending on the wavelength λ, in arbitrary units (a.u.), of the radiation emitted by an uncladded light-emitting diode LED, and a curve of evolution the C2 of the luminous intensity I of the radiation emitted by the array 15 of cladded light-emitting diode LED. For the curve C2, each insulating cladding 23 had a thickness equal to 120 nm. FIG. 9 shows an evolution curve C3 analogous to curve C2 for a direction inclined by +/−5° in relation to a direction perpendicular to the emission surface 30.

As shown in FIG. 8, a resonance peak P1 is obtained for the curve C2 at a wavelength that is different from the center wavelength of the radiation emitted by the light-emitting diodes LED. As shown in FIG. 9, a resonance peak P3 is obtained for the curve C3 at a wavelength that is different from the center wavelength of the radiation emitted by the light-emitting diode LED with a high amplification factor. A directional radiation is thus obtained.

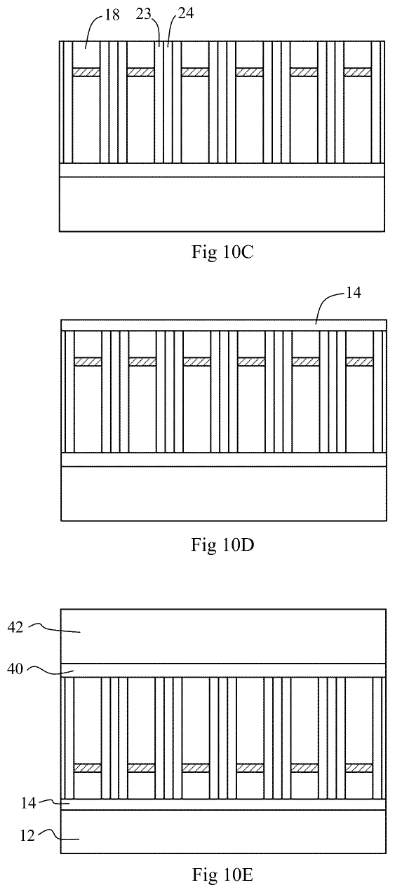

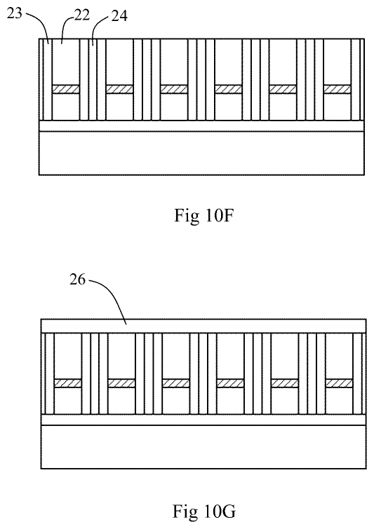

FIGS. 10A through 10G are schematic partial cross-sectional views of structures obtained in successive steps of one embodiment of a method for manufacturing the optoelectronic device 10 shown in FIG. 1.

FIG. 10A illustrates the structure obtained after the formation steps described below.

A seed layer 40 is formed on a substrate 42. Light-emitting diodes LED are then formed from the seed layer 40. Specifically, the light-emitting diodes LED are formed such that the top portions 22 are in contact with the seed layer 40. The seed layer 40 is made of a material that promotes the growth of the top portions 22. For each light-emitting diode LED, the active area 20 is formed on the top portion 22 and the bottom portion 18 is formed on the active area 20.

Further, the light-emitting diodes LED are located to form the array 15, i.e. to form rows and columns with the desired pitch of the array 15. Only one row is partially shown in FIGS. 10A through 10G.

A mask, not shown, may be formed prior to the formation of the LEDs on the seed layer 40, so as to expose only portions of the seed layer 40 at the locations where the LEDs will be located. In a variant, the seed layer 40 may be etched, prior to the formation of the LEDs, to form pads located at the locations where the LEDs will be formed.

The method for growing the light-emitting diodes LED can be a chemical vapor deposition (CVD) or metal organic chemical vapor deposition (MOCVD) method, also known as metal organic vapor phase epitaxy (MOVPE). However, methods such as molecular beam epitaxy (MBE), gas source MBE (GSMBE), metal-organic MBE (MOMBE), plasma assisted MBE (PAMBE), atomic layer epitaxy (ALE) or hydride vapor phase epitaxy (HVPE) can be used. However, electrochemical methods can be used, such as chemical bath deposition (CBD), hydrothermal processes, liquid aerosol pyrolysis, or electrodeposition.

The growth conditions of the LEDs are such that all of the light-emitting diodes LED in the array 15 form at substantially the same rate. Thus, the heights of the semiconductor portions 22 and 18 and the height of the active area 20 are substantially the same for all the LEDs in the array 15.

According to one embodiment, the height of the semiconductor portion 22 is greater than the desired value h3. This is because it may be difficult to accurately control the height of the top portion 22 particularly due to the start of growth of the top portion 22 from the seed layer 40. In addition, forming the semiconductor material directly on the seed layer 40 may cause crystal defects in the semiconductor material just above the seed layer 40. Therefore, one may want to remove a portion of the top portion 22.

FIG. 10B illustrates the structure obtained after forming the claddings 23 of the first insulating material, such as silicon nitride, over the light-emitting diodes LED to obtain the cladded light-emitting diodes LED′. According to one embodiment, the claddings 23 are formed by CVD. According to another embodiment, a layer of the first insulating material is deposited on the entire structure shown in FIG. 10A, the layer having a thickness greater than the height of the light-emitting diodes LED. The layer of the first insulating material is then partially etched to define the claddings 23.

FIG. 10C illustrates the structure obtained after formation of the layer 24 of the second insulating material, such as silicon oxide. The layer 24 is formed by depositing a layer of filler material on the structure shown in FIG. 10B, for example, the layer having a thickness greater than the height of the light-emitting diodes LED. The layer of the second insulating material and the claddings 23 are then partially removed so as to be planarized, to expose the top surfaces of the semiconductor portions 18. The top surface of the layer 24 and the claddings 23 is then substantially coplanar with the top surface of each semiconductor portion 18. In a variant, the method may include an etching step, in which the semiconductor portions 18 are partially etched.

FIG. 10D illustrates the structure obtained after the electrode layer 14 is deposited on the structure obtained in the previous step.

FIG. 10E illustrates the structure obtained after the layer 14 is attached to the support 12 by metal-to-metal bonding for example, or thermo-compression, or soldering with the use of a eutectic on the side of the support 12.

FIG. 10F illustrates the structure obtained after removal of the substrate 42 and the seed layer 40. In addition, the layer 24, the claddings 23 and the top portions 22 are etched such that the height of each top portion 22 has the desired value h3. Advantageously, this step allows for exact control of the height H of the LEDs and removal of parts of the top portions 22 that may have crystal defects.

FIG. 10G illustrates the structure obtained after deposition of the electrode layer 26.

The method may further comprise forming at least one optical filter on all or a portion of the structure shown in FIG. 10G.

Various embodiments and variants have been described. Those skilled in the art will understand that certain features of these embodiments can be combined and other variants will readily occur to those skilled in the art. In particular, the coating 28 described above may include additional layers other than an optical filter or filters. In particular, the coating 28 may comprise an anti-reflective layer, a protective layer, etc. Finally, the practical implementation of the embodiments and variants described herein is within the capabilities of those skilled in the art based on the functional description provided hereinabove. In addition, the refractive index values for the materials making up the LEDs have been given in the case of Group III-VI compound LEDs. When the LEDs are based on Group II-VI compounds, or a Group IV semiconductor or compound, it is clear that these numerical refractive index values must be adapted.

1. An optoelectronic device comprising an array of axial light-emitting diodes each comprising an active area configured to emit electromagnetic radiation whose emission spectrum comprises a maximum at a first wavelength, the device further comprising a cladding for each light-emitting diode, transparent to said radiation, made of a first material surrounding the sidewalls of the light-emitting diode over at least a portion of the light-emitting diode, each cladding having a thickness greater than 10 nm, the device further comprising a layer between the claddings, transparent to said radiation, of a second material, different from the first material, the second material being electrically insulating, the array forming a photonic crystal.

2. The device according to claim 1, wherein each cladding has a thickness greater than 20 nm.

3. The device according to claim 1, wherein the refractive index of the first material at the first wavelength is strictly greater than the refractive index of the second material at the first wavelength.

4. The device according to claim 3, wherein the difference between the refractive index of the first material at the first wavelength and the refractive index of the second material at the first wavelength is greater than 0.5.

5. The device according to claim 1, wherein each light-emitting diode comprises a semiconductor element of a third material and at least partially surrounded by said cladding, the difference between the refractive index of the first material and the refractive index of the third material is less than 0.5, and preferably less than 0.3.

6. The device according to claim 1, wherein the first material is electrically insulating.

7. The device according to claim 1, further comprising an electrically insulating coating for each light-emitting diode, interposed between the cladding and the light-emitting diode, the thickness of the coating being less than 10 nm.

8. The device according to claim 1, wherein the light-emitting diodes each comprise a portion of a Group III-V compound, a Group II-VI compound, or a group IV semiconductor or compound.

9. The device according to claim 1, wherein the first material is silicon nitride or titanium oxide.

10. The device according to claim 1, wherein the second material is silicon oxide.

11. The device according to claim 1, wherein the photonic crystal is configured to form a resonance peak amplifying the intensity of said electromagnetic radiation at at least a second wavelength (∥_{T1}) different from or equal to the first wavelength.

12. The device according to claim 1, comprising a support on which the light-emitting diodes rest, each light-emitting diode comprising a stack of a first semiconductor portion resting on the support, the active area in contact with the first semiconductor portion and a second semiconductor portion in contact with the active area.

13. The device according to claim 12, comprising a reflective layer between the support and the first semiconductor portions of the light-emitting diodes.

14. The device according to claim 13, wherein the reflective layer is metal.

15. The device according to claim 12, wherein the second semiconductor portions of the light-emitting diodes are covered with a conductive layer and at least partially transparent to the radiation emitted by the light-emitting diodes.

16. A method for designing an optoelectronic device comprising axial light-emitting diodes, each comprising an active area, the method comprising the following steps:
determining a first target wavelength for the optoelectronic device;
determining the light-emitting diodes dimensions such that each active area emits electromagnetic radiation whose emission spectrum includes the first target wavelength; and
determining the dimensions of an array of said light-emitting diodes comprising a cladding for each light-emitting diode, transparent to said radiation of a first material surrounding the sidewalls of the light-emitting diode over at least a portion of the light-emitting diode, each cladding having a thickness greater than 10 nm and further comprising a layer between the claddings, transparent to said radiation of a second material, different from the first material, the second material being electrically insulating, to obtain a photonic crystal forming a resonance peak amplifying the intensity of said electromagnetic radiation at the first target wavelength.

17. A method for manufacturing an optoelectronic device comprising an array of axial light-emitting diodes, each comprising an active area configured to emit electromagnetic radiation whose emission spectrum includes a maximum at a first wavelength, the device further comprising a cladding for each light-emitting diode, transparent to said radiation, made of a first material surrounding the sidewalls of the light-emitting diode over at least a portion of the light-emitting diode, each cladding having a thickness greater than 10 nm, the device further comprising a layer, between the claddings, transparent to said radiation made of a second material, different from the first material, the second material being electrically insulating, the array forming a photonic crystal.

18. The method according to claim 17, wherein forming the light-emitting diodes comprises the following steps:
forming second semiconductor portions on a substrate, the second semiconductor portions being separated from each other by the pitch of the array;
forming an active area on each second semiconductor portion;
forming a first semiconductor portion on each active area;
forming the cladding for each light-emitting diode of a first material surrounding the sidewalls of at least part of the first portion, and/or of the second portion, and/or of the active area; and
forming the layer of the second material.

19. The method according to claim 18, comprising a step of removing the substrate.
